(19) United States
(12) Patent Application Publication
(10) Pub. No.: US 2026/0068615 A1
(43) Pub. Date: Mar. 5, 2026

(54) PRODUCTION METHOD FOR OPTICAL SEMICONDUCTOR ELEMENT

(71) Applicant: DOWA Electronics Materials Co., Ltd., Chiyoda-ku, Tokyo (JP)

(72) Inventors: Mako KANEMOTO, Akita-shi, Akita (JP); Masayuki NAKANO, Akita-shi, Akita (JP)

(73) Assignee: DOWA Electronics Materials Co., Ltd., Chiyoda-ku, Tokyo (JP)

(21) Appl. No.: 19/111,787

(22) PCT Filed: Sep. 8, 2023
(86) PCT No.: PCT/JP2023/032925

§ 371 Date: Mar. 14, 2025

(30) Foreign Application Priority Data
Sep. 16, 2022 (JP) 2022-148612

(51) Int. Cl. H01L 21/02; H01L 21/28

(52) U.S. Cl. CPC H01L 21/02013

(57) ABSTRACT

Provided is a production method for an optical semiconductor element with a high yield by preventing wafer damage caused by grinding. A production method for an optical semiconductor element comprises: a step of forming a laminate of compound semiconductor layers on one main surface of a compound semiconductor substrate having cleavability; and a grinding step of grinding the other main surface of the compound semiconductor substrate, wherein a skewness (Ssk) in surface roughness measurement of a ground surface of the compound semiconductor substrate immediately after the grinding step is positive.

### TECHNICAL FIELD

The present disclosure relates to a production method for an optical semiconductor element such as a light emitting element or a light receiving element, including a step of grinding a substrate of a compound semiconductor having cleavability.

### BACKGROUND

Light emitting elements and light receiving elements using a substrate of a compound semiconductor having cleavability, such as an InP substrate or a GaAs substrate, are widely used. Such light emitting elements or light receiving elements emit or receive infrared light and are in wide use in optical fibers, various infrared sensors, etc.

For example, JP 2018-6495 A (PTL 1) discloses that grinding an InP substrate to less than 200 μm, for example 150 μm or less, causes damage because of brittleness of the InP substrate.

### CITATION LIST

### Patent Literature

PTL 1: JP 2018-6495 A

### SUMMARY

### Technical Problem

With size reduction of light receiving/emitting devices using infrared light, reduction of the overall thickness of the element is required. Since most of the thickness of the element is taken up by the substrate, the thickness of the element can be reduced by reducing the thickness of the substrate. However, if the substrate does not have a sufficient thickness of, for example, 300 μm or more during epitaxial growth and subsequent electrode formation, the substrate is susceptible to warping or damage. Hence, for reduction of the thickness of the substrate, it is necessary to use a sufficiently thick substrate and, before cutting into individual chips in a later step, grind the substrate to reduce its thickness to less than 200 μm.

Compound semiconductor substrates having cleavability such as the InP substrate described in PTL 1 are very brittle and are easily damaged when thinned by grinding. It could therefore be helpful to provide a production method for an optical semiconductor element with a high yield by preventing wafer damage caused by grinding.

### Solution to Problem

Intensive studies made to achieve the object stated above led to the present disclosure.

We thus provide:
(1) A production method for an optical semiconductor element, comprising: a step of forming a laminate of compound semiconductor layers on one main surface of a compound semiconductor substrate having cleavability; and a grinding step of grinding the other main surface of the compound semiconductor substrate, wherein a skewness (Ssk) in surface roughness measurement of a ground surface of the compound semiconductor substrate immediately after the grinding step is positive.
(2) The production method for an optical semiconductor element according to (1), wherein a maximum height (Sz) in the surface roughness measurement of the ground surface immediately after the grinding step is 1.9 μm or more.
(3) The production method for an optical semiconductor element according to (1) or (2), wherein only a medium grinding wheel with a grain size of #800 to #2000 is used in the grinding step.
(4) The production method for an optical semiconductor element according to any one of (1) to (3), wherein the compound semiconductor substrate is an InP substrate.
(5) The production method for an optical semiconductor element according to any one of (1) to (4), further comprising, after the grinding step: an etching step of etching the ground surface; and a back electrode formation step of forming an electrode on the ground surface and performing heat treatment.
(6) The production method for an optical semiconductor element according to (5), wherein the etching step includes: a first etching step using a diluted sulfuric acid-hydrogen peroxide mixture; and a second etching step using a mixed solution of hydrochloric acid and acetic acid.

### Advantageous Effect

It is thus possible to provide a production method for an optical semiconductor element with a high yield by preventing wafer damage caused by grinding.

### BRIEF DESCRIPTION OF THE DRAWINGS

In the accompanying drawings:

FIG. 1 is a schematic diagram of a production method for an optical semiconductor element;

FIG. 2 is a diagram explaining the shape of the outer periphery of a substrate used in the present disclosure; and

FIG. 3 is a diagram illustrating a roughness profile in an example of the present disclosure.

### DETAILED DESCRIPTION

Prior to describing an embodiment of the present disclosure, the following points will be explained in advance.

### <Compound Semiconductor Substrate Having Cleavability>

A compound semiconductor substrate (hereafter sometimes abbreviated as “substrate”) having cleavability in this embodiment is a compound semiconductor substrate having a cubic zinc blende crystal structure, and may be any of GaAs, InP, GaP, InAs, GaSb, InSb, and ZnSe. GaAs or InP is preferable because of the ease of producing optical semiconductor elements. Since InP substrates are more likely to crack than GaAs substrates, the present disclosure is particularly useful in the case where InP is used.

### <Surface Roughness Measurement>

In surface roughness measurement, surface roughness parameters such as skewness (Ssk) and maximum height (Sz) can be measured using a non-contact shape analysis laser microscope (VK-X1000/1100 produced by Keyence Corporation). The surface roughness parameters are in accordance with ISO 25178-2:2012.

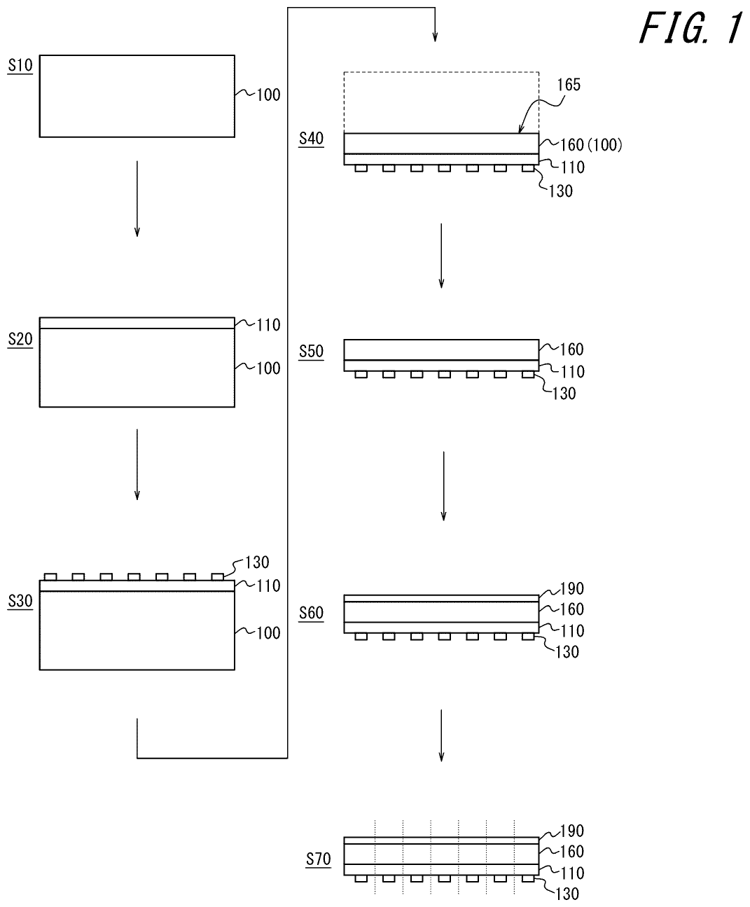

A production method for an optical semiconductor element according to the present disclosure will be described in detail below with reference to FIG. 1.

### <Substrate>

A substrate 100 used in S10 in FIG. 1 is a compound semiconductor substrate having cleavability and having a cubic zinc blende crystal structure as mentioned above. The conductivity type and impurity concentration of the substrate 100 are not limited. The thickness and diameter of the substrate 100 can be selected from the thicknesses and diameters of commercially available substrates. For example, the substrate 100 has a thickness of 300 μm to 2 mm and a diameter of 2 inches to 6 inches before grinding. The surface orientation and off-angle of the substrate 100 are not limited. The substrate 100 may be double-sided mirror or single-sided mirror, but it is preferable to use a double-sided mirror substrate.

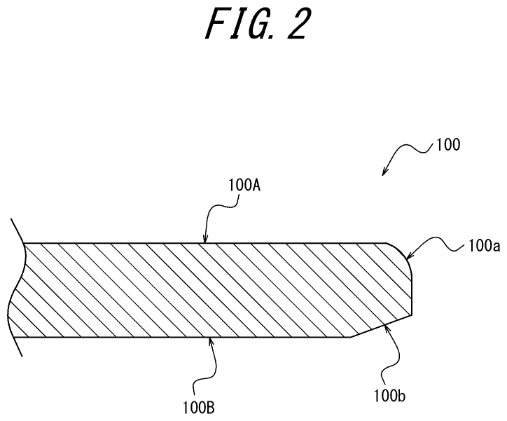

The shape of the outer periphery of the substrate 100 illustrated in S10 in FIG. 1 will be described with reference to FIG. 2. Typically, the shape (also referred to as “bevel shape”) of the outer periphery of the substrate 100 as seen in a direction perpendicular to a section of the substrate 100 may have a straight line or a curve inclined with respect to the principal surface (also referred to as “main surface”) or a combination of a straight line and a curve inclined with respect to the principal surface, as a result of chamfering. The inclined straight line in the vertical sectional view may be formed on both the front side 100A and the back side 100B or on only one of the front side 100A and the back side 100B. The shape resulting from chamfering preferably has a curved portion 100a illustrated in FIG. 2 in order to prevent damage, slippage during crystal growth, and the like. The shape resulting from chamfering preferably has a straight portion 100b inclined with respect to the principal surface only on the back side 100B in order to reduce the impact with the grinding wheel in the early stage of a back grinding step S40 and prevent damage. If the shape resulting from chamfering has a straight portion inclined with respect to the principal surface on both the front side 100A and the back side 100B, it is preferable that the straight portion inclined with respect to the principal surface is longer on the back side 100B than on the front side 100A.

### <Epitaxial Growth Step S20>

Returning to FIG. 1, in an epitaxial growth step S20, a laminate 110 of compound semiconductor layers having a composition capable of epitaxial growth is formed on the front side 100A of the substrate 100. The compound semiconductor layers to be laminated may have a composition that is known to be formable on the substrate 10 depending on the material of the substrate 100, and are preferably of a lattice-matched system with a low lattice mismatch degree. Even if the lattice mismatch degree is high, forming an appropriate buffer layer on the substrate enables epitaxial growth. On a GaAs substrate, for example, a laminate of AlGaAs-based semiconductor layers, a laminate of AlInGaP-based semiconductor layers, and a laminate of a mixture of these layers are formed in the epitaxial growth step S20. On an InP substrate, for example, a laminate of InGaAs-based semiconductor layers, a laminate of InGaAsP-based semiconductor layers, a laminate of InGaAlAs-based semiconductor layers, and a laminate of a mixture of these layers are formed in the epitaxial growth step S20.

### Thickness and Warping

The thickness of the laminate 110 is preferably 1 μm to 20 μm. The substrate 100 warps due to the differences in lattice constant and thermal expansion coefficient between the substrate 100 and the laminate 110. Thus, the substrate 100 having the laminate 110 formed thereon contains internal stress and therefore is more likely to be damaged during grinding than the substrate 100 without the laminate 110 formed thereon.

If the warp of the substrate 100 is excessively large in the below-described upper electrode formation step S30, back grinding step S40, etching step S50, back electrode formation step S60, and singulation step S70, the substrate is damaged when it is fixed to a stage by suction and flattened in each step. Therefore, it is preferable that the thickness of the laminate 110 in the epitaxial growth step S20 is set so that the warp will have such size and shape that do not lead to damage before grinding in the subsequent back grinding step S40.

### <Upper Electrode Formation Step S30>

As an upper electrode 130, an appropriate known electrode may be used depending on the layer on which the upper electrode 130 is formed. As its metal, any of combinations of precious metals such as Au (gold) and Pt (platinum) and metals such as Ti (titanium), Zn (zinc), and Ni (nickel) is preferably used. For example, Ti (titanium), Pt (platinum), and Au (gold) may be used in a laminated state. The upper electrode 130 can be formed by a lift-off method in which an upper electrode pattern is formed in advance by a photoresist, then a metal layer that is to form the upper electrode 130 is formed by vapor deposition, sputtering, or the like, and then the photoresist is removed, or a method in which a metal layer is formed, then an upper electrode pattern is formed by a photoresist, and the unnecessary metal layer is removed by etching or the like. In FIG. 1, the upper electrode 130 is formed in dots, as an example.

### <Back Grinding Step S40>

In the back grinding step S40 in the present disclosure, back grinding is performed so that the skewness (Ssk) in the surface roughness measurement of the ground surface immediately after grinding will be positive. Moreover, the maximum height (Sz) in the surface roughness measurement of the ground surface immediately after the back grinding step S40 is preferably 1.9 μm or more, and it is preferable to use only a medium grinding wheel with a grain size of #800 to #2000 in the grinding step S40.

The reason why damage during grinding is prevented in this way is considered as follows: If the skewness (Ssk) is positive and the surface has many fine peaks, the shavings of the substrate 100 generated during grinding can escape from between the back surface of the substrate 100 and the grinding wheel through the gaps between the peaks, and therefore do not accumulate between the back surface of the substrate 100 and the grinding wheel. If the skewness (Ssk) is negative and the surface has many fine valleys, the shavings accumulate without being able to escape from between the back surface of the substrate 100 and the grinding wheel, which may impose a load in such a direction that widens the valleys. A larger maximum height (Sz) is preferable because it is easier to secure an escape route for the shavings.

The use of only a medium grinding wheel with a grain size of #800 to #2000 is considered preferable because the irregularities of the grinding wheel provide an escape route for the shavings and because the foregoing positive skewness (Ssk) state can be created easily. If a finishing grinding wheel with a grain size of #3000 or more is used as the grinding wheel, a flat surface can be obtained but the skewness (Ssk) tends to be negative, which is likely to cause damage. The thickness of the substrate 160 after back grinding is preferably less than 200 μm. The thickness of the substrate 160 after back grinding is preferably 60 μm to 180 μm.

### Fixing of Substrate to Grinding Stage

In order to grind the back surface of the substrate, the front side of the substrate needs to be fixed to the grinding stage. The laminate of semiconductor layers, the upper electrode, etc. are formed on the front side of the substrate, and the front side of the substrate needs to be fixed to the grinding stage without damaging these components. In order to prevent damage, it is preferable to perform, on the front side of the substrate, one or more selected from the following:
applying a resist to the epitaxial surface side as a protective film
attaching an ultraviolet curable sheet
attaching a support plate that has a similar shape to the substrate and can be peeled away after adhesion.

Examples of the fixing to the grinding stage include fixing by suction and fixing to a ceramic plate or the like using resin (wax).

### Use of Slurry

During grinding, it is preferable to flow a grinding fluid over the surface of the compound semiconductor substrate to be ground. The grinding fluid serves to remove the shavings from the system and also cool the ground surface. In typical grinding and polishing, the grinding fluid may contain abrasive grains or abradants. In the present disclosure, if abrasive grains or abradants are contained, damage is likely to be caused due to clogging, and accordingly it is preferable to use water or pure water as the grinding fluid. The grinding fluid may contain a surfactant.

Process after Grinding

After grinding, the substrate is released from the grinding stage. The resist, ultraviolet curable sheet, support plate, etc., which are provided on the front side of the substrate to prevent damage to the substrate, may be maintained until the completion of the subsequent steps or removed immediately after the back grinding step S40.

### <Etching Step S50>

After the back grinding step S40, impurities such as oxides may adhere to the ground surface 165. If an electrode is formed in this state, the contact resistance may increase or the electrode may peel off easily. It is therefore preferable to lightly etch the ground surface 165 after the back grinding step S40 to remove the impurities. The etchant liquid may be selected as appropriate depending on the type of the substrate. The etching amount is, for example, 1 nm to 100 nm in thickness. Since the protrusions due to positive skewness (Ssk) are preferentially etched in the etching step S50, cracks in the subsequent steps (the back electrode formation step S60, etc.) can be suppressed. For example, in the case where an InP substrate is used, the etching step S50 preferably includes a first etching step using a diluted sulfuric acid-hydrogen peroxide mixture and a second etching step using a mixed solution of hydrochloric acid and acetic acid.

### <<First Etching Step for Removing Impurities>>

It is preferable to use a diluted sulfuric acid-hydrogen peroxide mixture. The volume ratio of sulfuric acid (concentration 96%) and hydrogen peroxide solution (concentration 30.0% to 35.5%, also called hydrogen peroxide) can be in the range of 1:10 to 10:1, and is preferably 1:1, for example. The etching rate is high when only sulfuric acid and hydrogen peroxide are mixed. Since excessive etching can be prevented easily with a lower concentration, the mixture is diluted with pure water by 5 times or more and 15 times or less. For example, the volume ratio of sulfuric acid, hydrogen peroxide, and pure water is preferably 1:1:7.

### <<Second Etching Step for Removing Altered Layer>>

It is preferable to use a mixed solution of hydrochloric acid and acetic acid. The volume ratio of hydrochloric acid (concentration 35% to 37%) and acetic acid (concentration 99.7%) can be in the range of 1:10 to 10:1, and is preferably 1:1, for example. The etching rate is high when only hydrochloric acid and acetic acid are mixed. Since excessive etching can be prevented easily with a lower concentration, the mixture is diluted with pure water by 1 time or more and 5 times or less. For example, the volume ratio of hydrochloric acid, acetic acid, and pure water is preferably 1:1:2.

### <Back Electrode Formation Step S60>

A back electrode 190 may be selected as appropriate depending on the type of the substrate on which the back electrode 190 is formed. For example, for an InP substrate, it is preferable to use metals such as Au (gold), Al (aluminum), Pd (palladium), Ge (germanium), Ni (nickel), and Mo (molybdenum). An AuGe alloy may be used, for example. The back electrode 190 can be formed on the whole or part of the back surface of the substrate. After the back electrode is formed, it is preferable to perform ohmic heat treatment with a temperature and time suitable for the upper electrode 130 and the back electrode 190. In view of the heat resistance of the protective agent such as the resist on the front side, the ohmic heat treatment is preferably performed after removing the resist, etc. according to need.

### <Singulation Step S70>

In the singulation step S70, a blade dicer, a laser dicer, a scribe, etc. can be used. The chip size may be 200 μm to 3000 μm on a side. The chip shape may be any shape, but is preferably a square or rectangular shape that eases singulation for a substrate having cleavability.

### <Other Steps (Mesa Formation, Roughening, Protective Film Formation)>

The production method may further include one or more of a mesa formation step, a roughening step, and a protective film formation step before or after any of the steps subsequent to the epitaxial growth step S20. The mesa formation step is a step of etching the laminate of compound semiconductor layers at the locations where separation is to be performed in the singulation step S70. The roughening step is a step of roughening, by etching, the surface through which light mainly passes. The protective film formation step is a step of forming a dielectric film such as SiO₂ on the element surface other than the electrodes to prevent degradation of the element caused by the outside air and forming a film to suppress surface leakage current.

The present disclosure will be described in more detail below by way of an example, although the present disclosure is not limited to such an example.

### Examples

An undoped InP buffer layer, an undoped InGaAs light absorption layer, an undoped InP window layer, and an undoped InGaAs cap layer were sequentially formed by MOCVD on a double-sided mirror n-type InP substrate (3 inches, thickness: 625 μm, carrier density: 3.0×10¹⁸/cm³) with a bevel shape having a straight line and curve inclined with respect to the principal surface on the back side, thus forming a laminate to function as a light receiving element in an optical semiconductor element. The total thickness of the laminate was 4.4 μm.

Next, a mask was formed on the cap layer and etching was performed, and then a SiN film (thickness: 0.1 μm) was formed by CVD. A pattern was formed by photolithography using a resist, and Zn was diffused by MOCVD from the cap layer into the undoped InP window layer and the undoped InGaAs light absorption layer.

After this, an upper electrode (Ti (titanium)/Pt (platinum)/Au (gold)) was formed by vapor deposition so as to have openings as light receiving portions on the cap layer.

A protective film was then formed using a photoresist on the side on which the upper electrode was formed, and then ultraviolet curable tape was applied and the side on which the upper electrode was formed was fixed by suction to the grinding stage of a grinder via the ultraviolet curable tape. Following this, a circular grinding wheel was pressed against the back surface of the InP substrate by weighting while running pure water, and the back side of the InP substrate was ground from 625 μm to 150 μm in thickness by the rotational movement of the substrate and the circular grinding wheel. A manual grinder (DAG810) produced by Disco Corporation was used for grinding, and the grinding conditions were a grinding wheel grain size of #2000 (GF01-SD2000-BR440-100 produced by Disco Corporation), a spindle of 2000 rpm, a chuck table of 97 rpm, and a grinding speed of 1.50 μm/sec. Subsequently, when the suction fixation to the grinding stage was released, whether there was wafer damage was visually checked. For ten wafers produced under the same conditions, the wafer damage rate was evaluated.

Surface roughness measurement was performed at any nine locations on the ground surface immediately after grinding using a shape analysis laser microscope (VK-X1000/1100 produced by Keyence Corporation), and the average value was calculated. The measurement conditions were a lens magnification of 150 times, the number of pixels of 2048×1536, and use of Gaussian filter. Specific input parameters for the surface roughness measurement device were as follows:
Sal, Str: s=0.20
Sxp: p=2.5%
Vvv: p=80.0%
Vvc: p=10.0%, q=80.0%
Vmp: p=10.0%
Vmc: p=10.0%, q=80.0%.

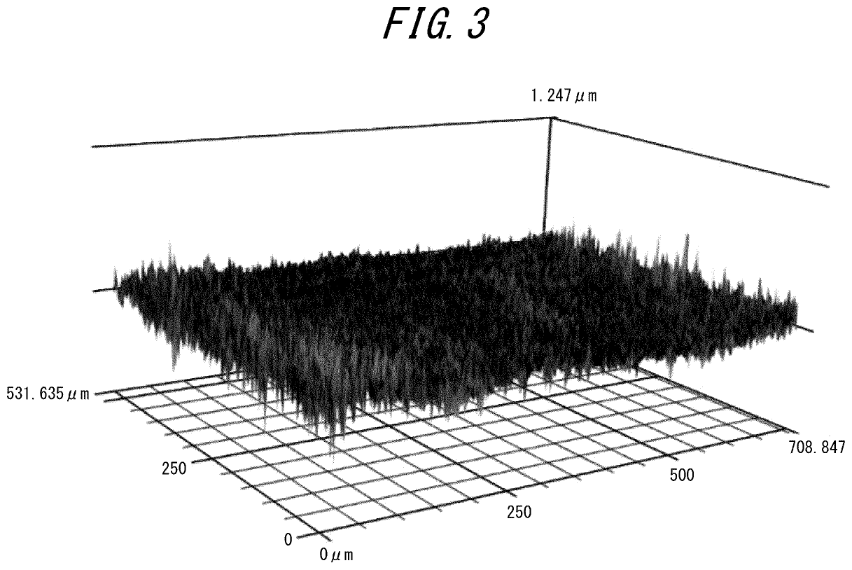

Table 1 shows automatically calculated surface roughness parameters Sa (arithmetic mean height), Sz (maximum height), Sq (root mean square height), Sdr (developed interfacial area ratio), Spc (arithmetic mean curvature of peak), Ssk (skewness), and Sku (kurtosis) according to ISO 25178-2:2012. Table 1 also shows the values of the below-described Comparative Example and Reference Example. As a representative example, FIG. 3 illustrates the surface roughness measurement results of Example using a shape analysis laser microscope at any one location on the ground surface immediately after grinding.

### [Table 1]

TABLE 1

| | | Surface roughness of ground surface | | | | | | | | |
|---|---|---|---|---|---|---|---|---|---|---|
| | Grinding | immediately after grinding | | | | | | | Wafer damage rate | |
| | wheel | Sa | Sz | Sq | Sd | Spc | Ssk | Sku | 2 inches | 3 inches |
| Unit | Grain size | μm | μm | μm | — | 1/mm | — | — | Damage rate | Damage rate |
| Example | #2000 | 0.223 | 2.334 | 0.271 | 0.019 | 411 | 0.112 | 2.568 | 0/10 | 0/10 |
| Comparative Example | #4800 | 0.206 | 1.529 | 0.244 | 0.002 | 142 | −0.005 | 2.146 | 1/10 | 4/10 |
| Reference Example | — | 0.728 | 11.584 | 0.968 | 0.396 | 2173 | −0.345 | 4.858 | — | — |

Subsequently, with a resist applied to the front side, the ground surface was subjected to a first etching step involving etching at 22° C. for 3 minutes using an etching solution with a volume ratio of sulfuric acid (concentration 96%), hydrogen peroxide (concentration 35%), and pure water of 1:1:7 and then to a second etching step involving etching at 22° C. for 30 seconds using an etching solution with a volume ratio of hydrochloric acid (concentration 36%), acetic acid (concentration 99.7%), and pure water of 1:1:2. Thus, the back surface was etched by about 6 nm to remove impurities generated due to grinding. A film of AuGe alloy was formed by sputtering on the etched back surface of the substrate, to form a back electrode. After removing the resist on the front side, heat treatment at 320° C. for 5 minutes was performed as ohmic heat treatment in the back electrode formation step. A singulation step was then performed using a laser dicer to obtain an infrared light receiving element.

### Comparative Example

An optical semiconductor element according to Comparative Example was produced in the same manner as in Example 1, except that the grain size of the grinding wheel was changed to #4800 (GF01-SD4800-BR440-100 produced by Disco Corporation) and the grinding conditions were a spindle of 2000 rpm, a chuck table of 99 rpm, and a grinding speed of 0.30 μm/sec.

### Reference Example

The surface roughness of the back lapped surface of a single-sided mirror n-type InP substrate (thickness: 625 μm, carrier density: 3.0×10¹⁸/cm³) was measured.

As shown in Table 1, the wafer damage rate can be reduced by performing back grinding so that the skewness (Ssk) will be positive and the maximum height (Sz) will be 1.9 μm or more in the surface roughness measurement of the ground surface immediately after grinding.

### INDUSTRIAL APPLICABILITY

The production method for an optical semiconductor element according to the present disclosure is useful for producing optical semiconductor elements with a high yield without substrate damage.

### REFERENCE SIGNS LIST

100 substrate
110 laminate
130 upper electrode
160 substrate after back grinding
165 back ground surface
190 back electrode

1. A production method for an optical semiconductor element, comprising:
a step of forming a laminate of compound semiconductor layers on one main surface of a compound semiconductor substrate having cleavability; and
a grinding step of grinding the other main surface of the compound semiconductor substrate,
wherein a skewness (Ssk) in surface roughness measurement of a ground surface of the compound semiconductor substrate immediately after the grinding step is positive.

2. The production method for an optical semiconductor element according to claim 1, wherein a maximum height (Sz) in the surface roughness measurement of the ground surface immediately after the grinding step is 1.9 μm or more.

3. The production method for an optical semiconductor element according to claim 1, wherein only a medium grinding wheel with a grain size of #800 to #2000 is used in the grinding step.

4. The production method for an optical semiconductor element according to claim 1, wherein the compound semiconductor substrate is an InP substrate.

5. The production method for an optical semiconductor element according to claim 1, further comprising, after the grinding step:
an etching step of etching the ground surface; and
a back electrode formation step of forming an electrode on the ground surface and performing heat treatment.

6. The production method for an optical semiconductor element according to claim 5, wherein the etching step includes:
a first etching step using a diluted sulfuric acid-hydrogen peroxide mixture; and
a second etching step using a mixed solution of hydrochloric acid and acetic acid.

7. The production method for an optical semiconductor element according to claim 2, wherein the compound semiconductor substrate is an InP substrate.

8. The production method for an optical semiconductor element according to claim 3, wherein the compound semiconductor substrate is an InP substrate.
